(19) United States
(12) Patent Application Publication
(10) Pub. No.: US 2007/0173069 A1
(43) Pub. Date: Jul. 26, 2007

(54) Method of forming insulating layer of semiconductor device

(76) Inventor: Jun-Seuck Kim, Seoul (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/516,751

(22) Filed: Sep. 7, 2006

(30) Foreign Application Priority Data
Jan. 20, 2006 (KR) 2006-0006082

(51) Int. Cl. H01L 21/31

(52) U.S. Cl. 438/758

(57) ABSTRACT

A method of forming an insulating layer on a silicon substrate in a process chamber is disclosed. The method comprises forming a nitride layer on the silicon substrate, and thereafter performing a thermal oxidation process on the silicon substrate and nitride layer, wherein the thermal oxidation process generates energized oxygen radicals penetrating the nitride layer, such that a lower silicon oxide layer is formed between the nitride layer and the silicon substrate, and such that an upper silicon oxide layer is simultaneously formed on an upper surface of the nitride layer.

### BACKGROUND OF THE INVENTION

1. Technical Field

Embodiments of the invention relate to a method of fabricating a semiconductor device. More particularly, embodiments of the invention relate to a method of forming an insulating layer of a semiconductor device.

This application claims the benefit of Korean Patent Application No. 10-2006-0006082, filed Jan. 20, 2006, the disclosure of which is hereby incorporated by reference in its entirety.

2. Discussion of Related Art

The evolution of semiconductor memory devices is one characterized in large part by increased data storage capacity and higher operating speeds, and therefore, greater integration densities. More densely integrated semiconductor devices necessarily require much smaller design rules (e.g., layout geometries and corresponding separation distances). Smaller and smaller design rules pose serious difficulties to engineers responsible for the fabrication of contemporary semiconductor devices. For example, emerging design rules are challenging the resolution capability of conventional photolithography equipment and related processes. Misalignments are increasingly likely due to diminishing margins. As a result, the reliability and production yield of semiconductor devices are threatened.

Due to increased integration density, the available substrate surface area in contemporary semiconductor devices is increasingly scarce. This scarcity has been addressed in one approach by an increasing use of vertically (relative to an assumed horizontally disposed primary surface of a substrate) stacked or layered components. One set of fabrication techniques related to multi-layered structure employ a so-called ‘double layer’ process adapted to connect overlaying metal layers using metal via contacts, and a so-called ‘stack transistor’ process adapted to stack two or more transistors on a semiconductor substrate in a vertical arrangement.

These techniques find ready application in the field of static random access memories (SRAM). SRAM is advantageously used in high-capacity cache memories in high-performance computer. SRAM operates with relatively low power consumption, but nonetheless enjoys relatively high input/output data transfer speeds. However, since SRAM is typically structured with six transistors per memory cell, there are considerable difficulties in densely implementing SRAM, as compared with other memory types. Therefore, the double layer process and the stack transistor process are commonly employed to mitigate the inherently large per memory cell size of SRAM. Conventional SRAM structures, thus, commonly include multiple, vertically stacked transistors.

An effective insulation layer is critical to the successfully implementation of a stacked multilayer semiconductor device. The insulation layer must provide adequate insulation between the adjacent conductive components (e.g., circuit patterns, conductive layers, or conductive elements). This is increasingly difficult to do as the separation distances between adjacent conductive components continue to shrink under the influence of contemporary design rules. Yet, the electrical performance of a semiconductor device is dependent upon the insulation properties of the insulating layer preventing electrical shorts between adjacent conductive components.

An insulating layer may be implemented in many different aspects of a semiconductor device, such as an isolation layer defining an active region and a field region, a gate oxide layer, and an insulating layer comprising various insulating materials, etc. In one embodiment related to a common MOSFET structure adapted for use in a volatile memory device, a gate oxide layer formed from an insulating layer and disposed between a semiconductor substrate and a gate electrode plays an important role in effectively forming a conductive channel between source and drain regions. Thus, a stacked structure composed of an oxide layer-nitride layer-nitride layer, a so-called ONO layer, capable of further increasing a dielectric constant is commonly used to form the gate oxide layer, rather than using a single-layer oxide. Further, in addition to the MOSFET, the ONO layer may also be used in a non-volatile memory device, such as a flash memory, to serve as an interlayer insulating layer between a floating gate and a control gate.

A conventional method of forming an ONO insulating layer will now be described in relation to FIGS. (FIGS.) 1A through 1C.

Referring to FIG. 1A, a first oxide layer 12 is formed on a semiconductor substrate 10 (e.g., a substrate formed from silicon) using a first Chemical Vapor Deposition (CVD) process adapted to deposit an oxide layer. Referring to FIG. 1B, a second CVD process is then performed to form nitride layer 14 on first oxide layer 12. Referring to FIG. 1C, the first CVD process (or another CVD process adapted to form an oxide layer) is performed to form second oxide layer 16 on nitride layer 14. This combination of layers forms an insulating layer having an ONO structure.

However, when oxide layers 12 and 16 and nitride layer 14 are formed on semiconductor substrate 10 using conventional CVD process(es) as illustrated in FIGS. 1A through 1C, a number of defects are commonly generated at an interface “A” between substrate 10 and first oxide layer 12.

Ideally, when a (silicon) oxide layer is formed on silicon substrate covalent bonds (i.e., chemical bonds formed between two atoms sharing a pair of electrons) would be uniformly formed between one silicon atom and two adjacent oxygen atoms. However, actual implementation practice is far from ideal, and a significant number of the oxygen atoms and/or silicon atoms do not participate in the formation of covalent bonds at the interface “A” between substrate 10 and first oxide layer 12. Such mis-bonded atoms result in various defects, such as weak Si—Si bonding, strained Si—O bonding, Si dangling bonding, and the like.

These defects are unfortunate because the operating characteristics of a MOS transistor is significantly influenced by the electrical charge characteristics of the gate oxide layer, including the interface charge traps existing at the interface between substrate 10 and first (gate) oxide layer 12. Charges within gate oxide layer 12 and at interface “A” between substrate 10 and gate oxide layer 12 may be divided into an interface trapped charge (Qit), a fixed oxide charge (Qf), an oxide trapped charge (Qot) and a mobile ionic charge (Qm). The interface trapped charge (Qit) is generated by the interface characteristics of substrate 10 and the gate oxide layer 12. The fixed oxide charge (Qf) is disposed about 3 nm inwardly from interface “A”. The fixed oxide charge (Qf) may be changed to an interface trapped charge by the presence of an unstable silicon bonding (Si—Si or Si—O). The oxide trapped charge (Qot) is related to the type and number of defects within gate oxide layer 12, but may be removed by a low-temperature thermal treatment. Yet, the mobile ionic charge (Qm) results form contamination by sodium (Na) or other alkali ions, and may migrate within gate oxide layer 12 when high temperature (about 100 Å or higher) or a high electric field intensity is applied.

A stability problem may be raised from the migration of mobile ionic charges, such as change a corresponding change in the threshold voltage of the effected MOS transistor. Thus, when numerous defects (Si—Si bonding, strained Si—O bonding, Si dangling bonding) exist at the interface between substrate 10 and a first (e.g., a gate) oxide layer 12, the corresponding dielectric constant of the oxide layer deteriorates from specifications due to the interface trapping effects. As a result, the electrical operating characteristics of a semiconductor device are adversely affected. Therefore, an insulating layer having improved insulating characteristics, more reliable formed within a semiconductor device is needed to accommodate further reductions in deign rules.

### SUMMARY OF THE INVENTION

Therefore, embodiments of the invention provide in one aspect a method of forming an insulating layer adapted for use within a semiconductor device capable of minimizing defects generated at an interface between a silicon layer (e.g., a silicon substrate) and an insulating layer.

Embodiments of the invention also provide a method of forming an insulating layer having improved insulation characteristics within a semiconductor device which result in a semiconductor device having improved operating characteristics and better production yields.

In one embodiment, the invention provides a method of forming an insulating layer in a process chamber, the method comprising; forming a first insulating layer on a silicon material, and thereafter, forming a second insulating layer between the silicon material and the first insulating layer.

In another embodiment, the invention provides a method of forming an insulating layer on a silicon substrate in a process chamber, the method comprising; forming a nitride layer on the silicon substrate; and thereafter, performing a thermal oxidation process on the silicon substrate and nitride layer, wherein the thermal oxidation process generates energized oxygen radicals penetrating the nitride layer to form a lower oxide layer between the nitride layer and the silicon substrate.

In another embodiment, the invention provides a method of forming an insulating layer on a silicon substrate in a process chamber, the method comprising; forming a nitride layer on the silicon substrate; and thereafter, performing a thermal oxidation process on the silicon substrate and nitride layer, wherein the thermal oxidation process generates energized oxygen radicals penetrating the nitride layer, such that a lower silicon oxide layer is formed between the nitride layer and the silicon substrate, and such that an upper silicon oxide layer is simultaneously formed on an upper surface of the nitride layer.

### BRIEF DESCRIPTION OF THE DRAWINGS

FIGS. 1A through 1C are sectional views illustrating a conventional method of forming an insulating layer having an ONO structure;

FIG. 2 is a schematic view illustrating the structure of an apparatus for performing a thermal oxidation process (hereinafter, referred to as ‘thermal oxidation processing system) employed to a method of forming an insulating layer according to an embodiment of the present invention;

FIG. 3 is a schematic view illustrating that a silicon oxide layer is formed on a silicon substrate;

FIG. 4 is a schematic view illustrating a plasma processing system employed to a method of forming an insulating layer according to an embodiment of the present invention;

FIGS. 5A through 5C illustrate processes of a method of forming an insulating layer according to an embodiment of the present invention; and

FIG. 6 is a sectional view illustrating the structure of a MOS transistor employing the insulating layer formed according to an embodiment of the present invention.

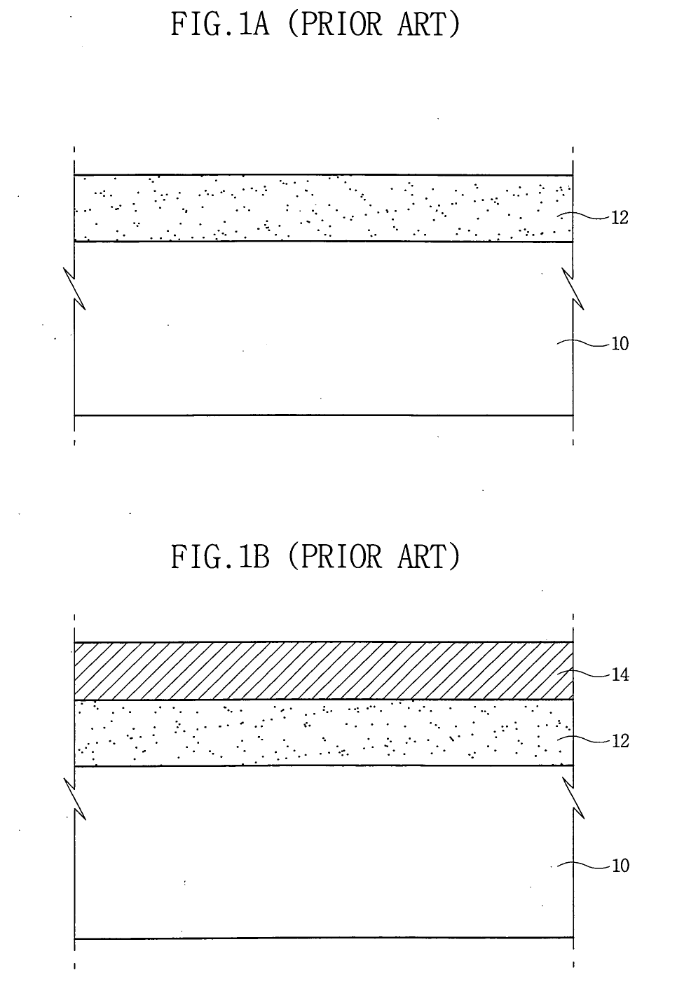

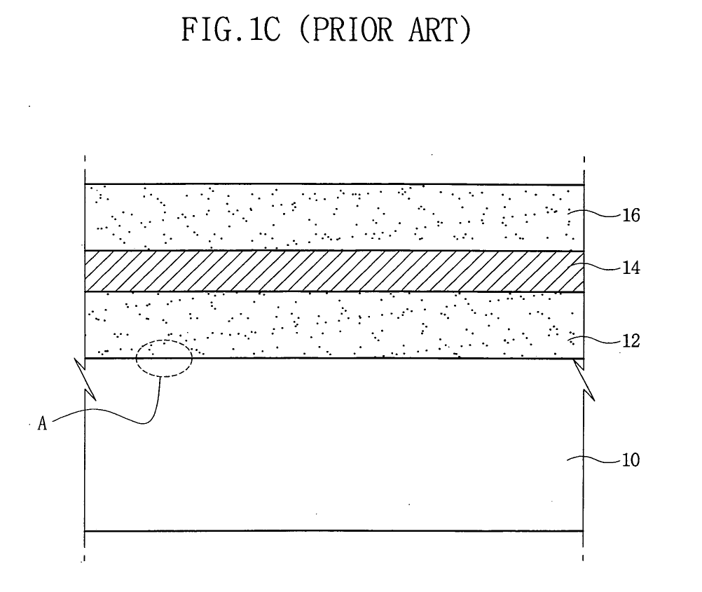

### DESCRIPTION OF EMBODIMENTS

Embodiments of the invention will now be described more fully with reference to the accompanying drawings. This invention may, however, be variously embodied in many different forms and should not be construed as being limited to only the embodiments set forth herein. Rather, the illustrated embodiments are presented as teaching examples.

Embodiments of the invention may be adapted to form various insulating layers among the many other material layers forming a semiconductor device. The various insulating layers formed in this regard may have many different shapes, and may serve many different purposes. Furthermore, embodiments of the invention may be used to form various insulating layers adapted for incorporation within a variety of semiconductor devices. However, as specific examples of more general application, embodiments of the invention drawn to the formation of an ONO layer disposed in a gate region of a MOS transistor or a flash memory device will be presented.

Normally, a semiconductor device is fabricated by depositing and patterning a multiplicity thin films (or material layers) having various characteristics on a principal surface of a substrate, such as a silicon wafer. Various insulating layers are included within this multiplicity of material layers. As already noted, the properties of an insulating layer are critical to the electrical performance of the semiconductor device. Insulating layers have conventionally been formed using such techniques as thermal oxidation, anodizing, and other deposition processes.

Deposition processes may be roughly divided into a physical vapor deposition (PVD) processes and a chemical vapor deposition (CVD) processes. In the context of contemporary semiconductor devices, CVD processes are more commonly used over PVD processes, since CVD processes provide excellent step coverage and may be more accurately deposited on a wafer.

Further, CVD processes may be divided into an atmospheric pressure CVD (APCVD) performed in an ambient atmospheric pressure environment, a low pressure CVD (LPCVD) performed in a low pressure environment, a light-excited CVD, or a plasma enhanced CVD (PECVD) performed in a plasma rich environment. The actual parameters for these CVD processes will vary in relation to the material layers being formed, and are most commonly defined in terms of pressure, temperature, applied energy, and staring materials.

Plasma enhanced CVD processes include high density plasma (HDP) processes performed in a low pressure environment in order to improve the ionized efficiency of chemical sources, as compared with those of typical PECVD processes. Since HDPCVD processes provide greater ion acceleration energy over PECVD processes, they generate a greater number of reaction radicals and a correspondingly high ionization density. As such, HDPCVD processes are actively employed in the formation of various conductive layers in highly integrated semiconductor devices in addition to the formation of insulating layers, such as oxide and/or nitride layers.

In addition to HPDCVD processes, thermal oxidation processes are also used to form insulting layers. Indeed, thermal oxidation processes are an important class of processes commonly employed to form insulating layers, particularly silicon oxide (SiO2) layers. Silicon oxide forms a very high quality insulating layer and may be thermally grown on a silicon substrate. A silicon oxide layer may function as a protection layer during an impurity diffusion process or an ion implantation process. Silicon oxide layers are also commonly used as a component later in MOS transistors and flash memory devices. Further, silicon oxide is often grown to function as a semiconductor material. For this reason, some embodiments of the invention provide a method of forming an improved insulating layer comprising silicon oxide, and more particularly, comprising both silicon oxide and silicon nitride in an ONO structure.

Hereinafter, a plasma processing system and a thermal oxidation processing system will be assumed as fabrication equipment competent to form an insulating layer according to an embodiment of the invention. An exemplary method of forming an insulating layer having an ONO structure according to an embodiment of the present invention using the plasma processing system and the thermal oxidation processing system will be explained.

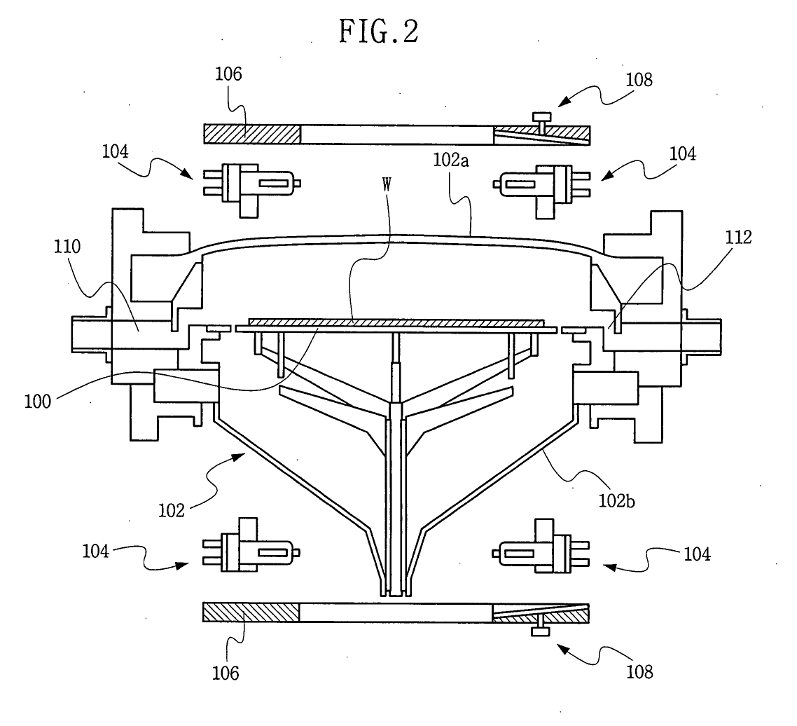

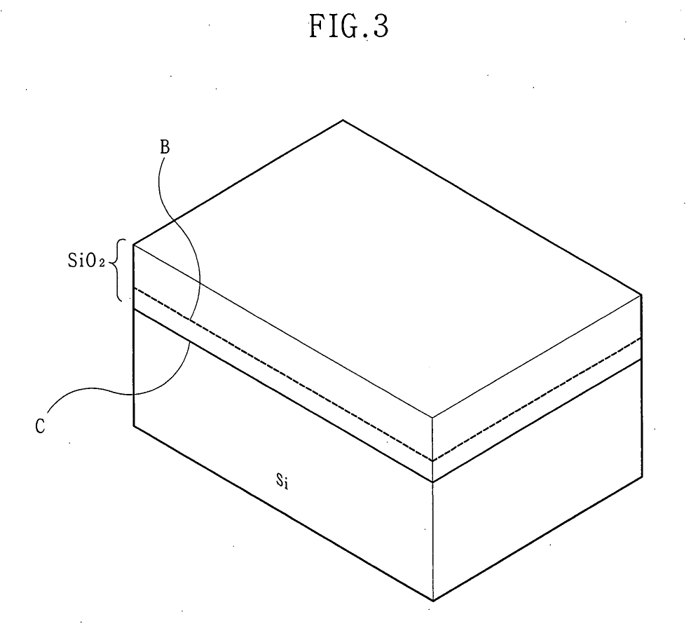

FIG. 2 illustrates a thermal oxidation processing system employed to a method of forming a silicon oxide layer according to an embodiment of the present invention.

Referring to FIG. 2, the thermal oxidation processing system includes a substrate loading unit 100 on which a silicon substrate W is mounted; a process chamber 102 covering substrate loading unit 100; heating units 104 respectively disposed above and below process chamber 102; a thermal reflection unit 106 reflecting heat generated from heating unit 104 toward heating loading unit 100; and a reflection angle control unit 108 controlling the angle of a reflection plate of thermal reflection unit 106.

Substrate loading unit 100 is a susceptor, and is disposed at the center of process chamber 102. Process chamber 102 includes an upper chamber 102a and a lower chamber 102b, which are composed of quartz, the inside of which maintains a vacuum state during the thermal oxidation process. In the illustrated example, a gas inlet unit 110 is disposed to one side of process chamber 102 and one or more process gas(es) adapted to the contemplated thermal oxidation process is supplied through gas inlet unit 110. A gas exhaust unit 112 is disposed to the other side of process chamber 102. Heating unit 104 is a heat source heating silicon substrate W. Heating units 104 are respectively disposed above upper chamber 102a and below lower chamber 102b, and supply heat to process chamber 102.

When performing a thermal oxidation process using the exemplary thermal oxidation processing system, oxygen gas and hydrogen gas are used as process gases. The thermal oxidation process performed in process chamber 102 may be represented in a chemical reaction formula, as follows.

Si+O2+H2→Si+O*+O+H2→SiO2+H2O

The oxidation process performed inside the thermal oxidation processing system is a radical oxidation process using oxygen radicals O*. This radical oxidation process will be described in some additional detail.

First, oxygen O2 and hydrogen H2 are supplied through gas inlet unit 110 to a silicon substrate W loaded into process chamber 102 in order to perform the thermal oxidation process. Then, process chamber 102 is maintained at a temperature of about 800 to 1050° C. by heating units 104. Since the oxygen radicals O* are better generated at low pressure, process chamber 102 is maintained at a low pressure of about 0.65 Torr.

After the inner environment of process chamber 102 has been thus prepared, the oxygen is supplied to process chamber 102 is thermally decomposed by the high temperature at low pressure and generates oxygen radicals O*. Oxygen radicals are oxidants, and readily bond with silicon atoms to form a silicon oxide layer. Since oxygen radicals have excellent reaction properties with silicon atoms, defects such as weak Si—Si bonding, strained Si—O bonding or Si dangling bonding are not so frequently formed at the interface between a silicon substrate and silicon oxide layer. In this manner, a very high quality silicon oxide layer may be formed. Oxygen atoms that do not bond with the silicon atoms (that is, non-radicalized oxygen atoms) bond, instead, with hydrogen to generate H2O. The generated H2O is exhausted from process chamber 102 through gas exhaust unit 112.

As alternatives to the radical oxidation process, a silicon oxide layer may be grown using a dry oxidation process or a wet oxidation process, which may be modeled by the equations Si+O2→SiO2 or Si+2H2O→SiO2+2H2.

FIG. 3 further illustrates a silicon oxide layer (SiO2) formed on a silicon substrate (Si) using any one of the foregoing techniques.

During formation of the silicon oxide layer, a materials interface C between the silicon substrate and the silicon oxide layer moves from the starting surface B of the silicon substrate down into the silicon substrate. For example, when a silicon oxide layer is to be formed with a thickness of ‘x’, the starting silicon surface is downwardly consumed by a thickness as much as ‘0.44×’. Thus, the silicon oxide layer is grown both upwardly from and downwardly into a starting surface of the silicon substrate by a thickness ratio of about 56:44.

When forming the silicon oxide layer (SiO2) using various techniques, including a method employing the thermal oxidation processing system illustrated in FIG. 2, it takes longer for oxygen to pass through an increasingly thick oxide layer. Thus, the silicon oxide growth rate for the oxide layer decreases with time. As a result, the growth rate of the silicon oxide layer proceeds in a non-linear manner according to the equation: R=X/^{√I}, where R is the growth rate (or propagation constant), X is the thickness of the oxide layer, and t is the oxidation process time.

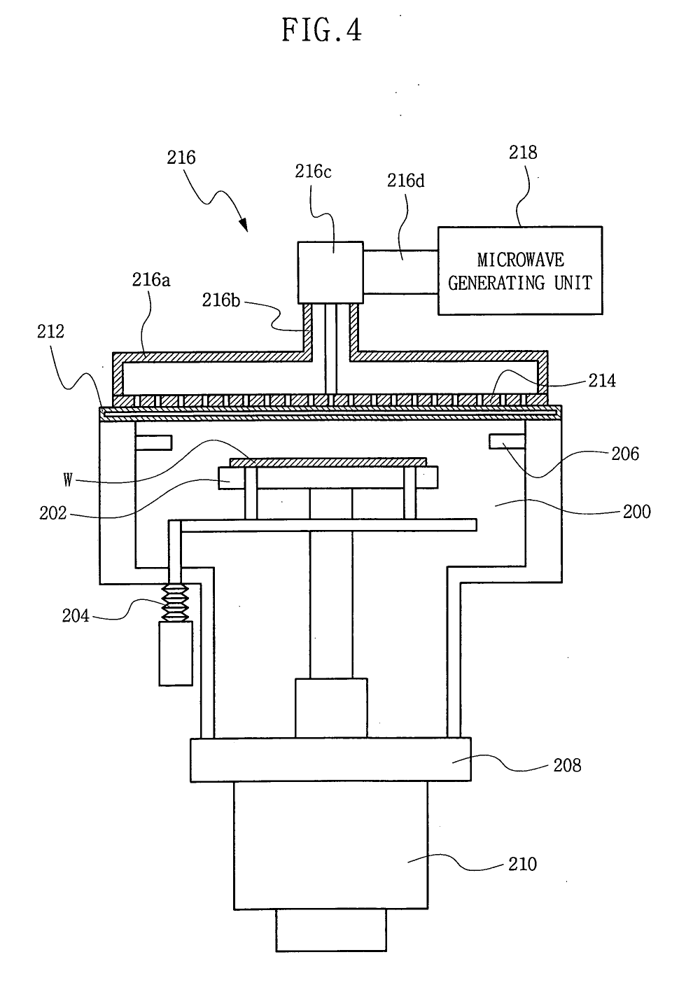

FIG. 4 illustrates a slot plane antenna (SPA) plasma processing system adapted for use in method forming a silicon nitride layer of insulating layers according to an embodiment of the present invention.

Referring to FIG. 4, the SPA plasma processing system includes a process chamber 200 wherein a plasma nitrification process takes place, and which is composed of, for example, aluminum. Process chamber 200 of the SPA plasma processing system includes a substrate loading unit 202 adapted to hold a silicon substrate W, a lifting unit 204 adapted to lift and lower silicon substrate W onto substrate loading unit 202, a gas injection unit 206 receiving an injected process gas, a vacuum pump 210 adapted to pump out process chamber 200, and a gate valve 208 separating process chamber 200 from vacuum pump 210.

A waveguide unit 216 and a microwave generating unit 218 are disposed on top of process chamber 200. Microwave generating unit 218 is a power source supplying the necessary power to generate the desired plasma. Waveguide unit 216 is physical energy path adapted to channel the energy generated by microwave generating unit 218 into process chamber 200. More specifically, waveguide unit 216 includes a plate waveguide 216a connected to a plane antenna 214, a cylindrical waveguide 216b connected with the plate waveguide 216a, a coaxial waveguide switch 216c connected to the cylindrical waveguide 216b, and a waveguide 216d connected between the coaxial waveguide switch 216c and the microwave generating unit 218.

An exemplary nitrification process performed in the plasma processing system described above will now be explained. First, silicon substrate W is securely mounted on substrate loading unit 202 inside sealed process chamber 200. Then, argon (Ar) gas is injected into process chamber 200, and about 1600 watts of microwave power is applied to generate a plasma. Thereafter, when nitrogen (N2) gas is injected into the plasma within process chamber 200, nitrogen atoms are energized and accelerated towards silicon substrate W by the bombardment of directed ions within the plasma. As the nitrogen atoms impact the silicon atoms of silicon substrate W, a silicon nitride layer (SiN) is formed.

With the foregoing examples in mind, a method of forming an insulating layer according to an embodiment of the present invention employing both the thermal oxidation processing system and the plasma processing system described with respect to FIGS. 2 and 4, respectively, will now be explained.

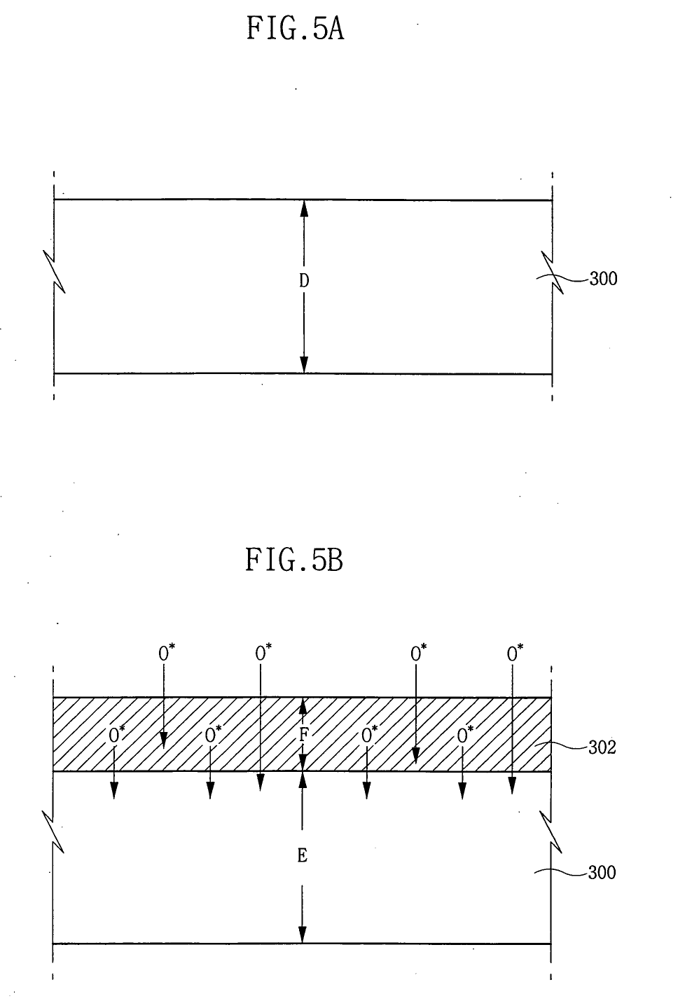

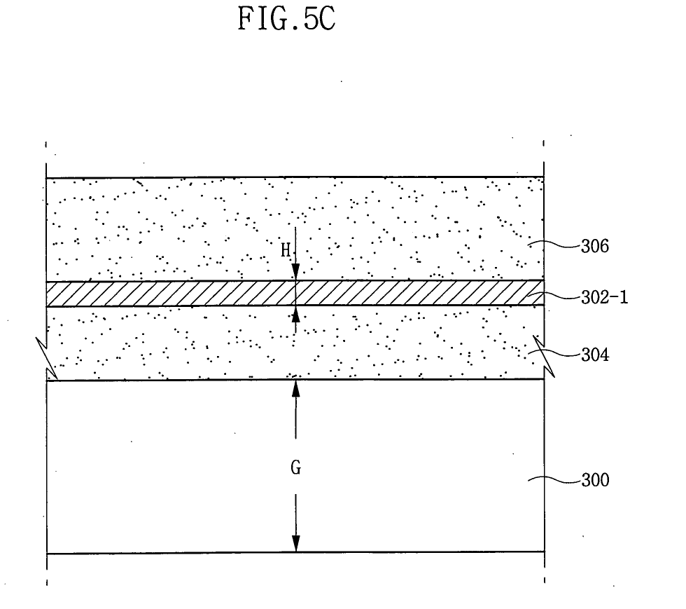

FIGS. 5A through 5C illustrate aspects of a method adapted to form an insulating layer having an ONO structure according to several embodiments of the present invention.

First, referring to FIG. 5A, a semiconductor substrate, for example, a silicon substrate 300 is loaded into the process chamber of the plasma processing system illustrated in FIG. 4. After about 200 cc of argon gas is introduced into the process chamber, between about 1000 to 2000 watts of microwave power are applied to the process chamber to generate an argon plasma. In one more specific embodiment, 1600 watts of microwave power are applied to the process chamber. The process chamber is maintained at an inner pressure of between about 0.3 to 0.7 Torr. In one more specific embodiment, the inner pressure of the process chamber is maintained at 0.5 Torr. Further, the process chamber is maintained at a temperature of between about 400 to 600° C., and in one more specific embodiment about 500° C. After about 150 cc of a nitrogen gas is introduced into the plasma contained within the process chamber, a nitrification process is performed on silicon substrate 300. By applying microwave energy to generate the plasma, interface damage between the silicon substrate and the silicon nitride layer is minimized.

During the nitrification process, nitrogen atoms are energized by the plasma within the process chamber and are accelerated into the silicon atoms of silicon substrate 300 to form a silicon nitride layer on the silicon substrate.

Referring now to FIGS. 5A and 5B, a silicon nitride layer (SiN) 302 is formed on silicon substrate 300 as the result of the nitrification process. At this time, comparing FIGS. 5A and 5B, after silicon nitride layer 302 is formed, the thickness E of the silicon substrate is thinner than the initial thickness D of the silicon substrate. This result occurs as atomic bonds between silicon atoms forming the silicon substrate are broken, and the liberated silicon atom bond to the impacting nitrogen atoms to form the silicon nitride layer. In other words, some upper thickness of the silicon layer is consumed in the formation of silicon nitride layer 302.

Thus, microwave energy is used to generate the argon gas plasma during the formation of silicon nitride layer 302 on silicon substrate 300. The use of microwave energy to generate the plasma minimizes interface damage between silicon substrate 300 and silicon nitride layer 302, as compared with an interface between similar materials formed using a conventional CVD process. However, bonding energy between silicon and nitrogen atoms as well as the density of the resulting silicon nitride layer 302 is less than those of a silicon nitride layer formed using a conventional CVD process. Thus, silicon nitride layer 302, standing alone on silicon substrate 300, provides insufficient insulation for many contemporary applications.

Nonetheless, a low bonding force between silicon (Si) and nitrogen (N) atoms forming silicon nitride layer 302, as well as the overall lower density thereof, prove important factors in a subsequently applied thermal oxidation process, as explained with reference to FIG. 5C. That is, the subsequent thermal oxidation process is a radical oxidation process using oxygen radicals. Thus, when the thermal oxidation process is performed on silicon substrate 300 having silicon nitride layer 302 formed thereon, thermally energized oxygen radicals O* pass through reduced density silicon nitride layer 302 to reach silicon substrate 300 and form a (lower) silicon oxide layer underlying silicon nitride layer 302.

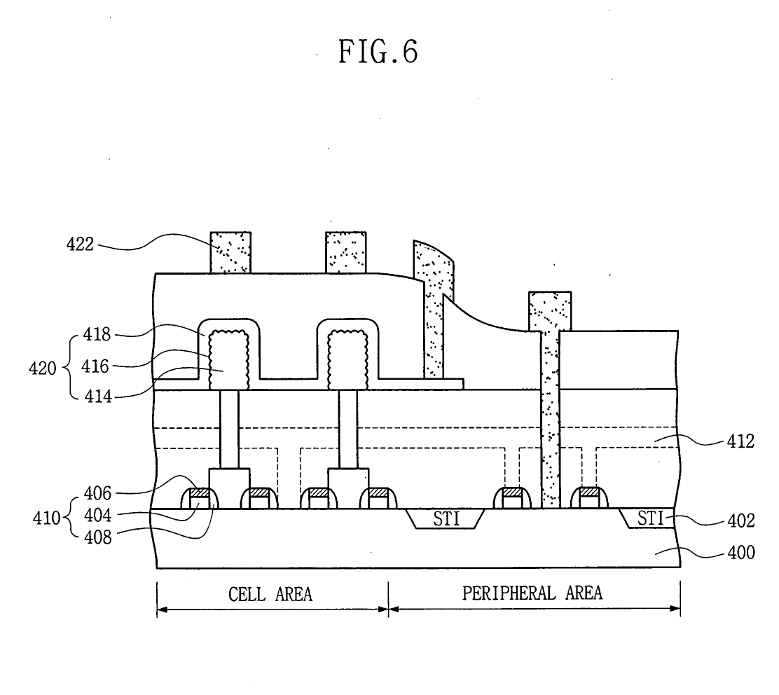

Simultaneously, with the formation of lower silicon oxide layer 304, (see, FIG. 6=5C), resulting from the thermal oxidation process, reduced density silicon nitride layer 302 is annealed to form a more dense (annealed) silicon nitride layer 302-1. Annealing of silicon nitride layer 302 takes place due to the thermal energy applied during the thermal oxidation process. Annealed silicon nitride layer 302-1 has much improved insulating properties over reduced density silicon nitride layer 302.

Referring to FIG. 5C, an exemplary thermal oxidation process adapted to the formation of lower silicon oxide layer 304 will be explained in some additional detail. After silicon nitride layer 302 is formed on silicon substrate 300 using the plasma processing system, silicon substrate 300 is loaded into the thermal oxidation processing system illustrated in FIG. 2. Then, the temperature of the process chamber is raised and maintained at between about 800 to 1050° C. and the inner pressure of the process chamber is raised and maintained at between about 6 to 7 Torr. In one more specific embodiment, the process chamber is maintained at a temperature of 950° C. and a pressure of 6.5 Torr. Then, about 9 liters of oxygen gas and about 1 liter of hydrogen gas are introduced through the gas inlet unit into the process chamber in order to form silicon nitride layer 302. The oxygen molecules are decomposed within the process chamber into oxygen radicals O* and oxygen atoms O by the applied thermal energy. The energized oxygen radicals pass through silicon nitride layer 302 and form lower silicon oxide layer 304 between silicon nitride layer 302 and silicon substrate 300.

Lower silicon oxide layer 304 is formed by two chemical reactions. First, lower silicon oxide layer 304 is formed by the chemical bonding between the silicon atoms existing on the surface of silicon substrate 300 and the oxygen radicals. Secondly, the oxygen radicals—having excellent reaction properties with silicon—break the bonds between the silicon and nitrogen atoms forming silicon nitride layer 302, and replace (i.e., substitute) the nitrogen atom in order to form lower silicon oxide layer 304.

Simultaneous to or sequentially after the formation of lower silicon oxide 304, an upper silicon oxide layer 306 may be formed on silicon nitride layer 302. In one embodiment, the same thermal oxidation process applied to silicon substrate 300 having silicon nitride layer 302 formed thereon, may be used to simultaneously form lower silicon oxide layer 304 and upper silicon oxide layer by means of the oxygen radicals generated in the thermal oxidation process. This particular approach to the formation of lower and upper silicon oxide layers 304 and 306 will be explained in some additional detail as follows.

First, as noted with reference to FIG. 5B, silicon substrate 300 having silicon nitride layer 302 formed thereon is loaded into the thermal oxidation processing system. Then, the oxygen radicals generated by the thermal oxidation processing system pass down through silicon nitride layer 302. Silicon nitride layer 302 is a reduced density nitride layer formed by plasma generated by applying microwave energy and is characterized by a weak bonding force between silicon and nitrogen atoms and relatively low density. As such, energized oxygen radicals readily penetrate silicon nitride layer 302, to reach silicon substrate 300.

The oxygen radicals penetrating silicon nitride layer 302 chemically bond with silicon atoms in silicon substrate 300 to form lower silicon oxide layer 304 between silicon nitride layer 302 and silicon substrate 300. In addition to the chemical bonding between oxygen radicals and silicon atoms in silicon substrate 300, a portion of lower silicon oxide layer 304 is formed by replacing the nitrogen atoms bonded to silicon atoms with the oxygen radicals. Thus, lower silicon oxide layer 304 is formed by two mechanisms (1) the bonding between the oxygen radicals and the silicon atoms on the surface of the silicon substrate, and (2) replacement of the nitrogen atoms bonding with the silicon atoms by the oxygen radicals.

During the formation of lower silicon oxide layer 304, silicon nitride layer 302 functions as a buffer layer to pass only oxygen radicals having a predetermined energy level or higher. That is, oxygen radicals generated from the thermal oxidation processing system having energy levels below the predetermined energy level do not pass through silicon nitride layer 302. As a result, lower silicon oxide layer 304 may be grown below silicon nitride layer 302 using only a portion of the generated oxygen radicals having a relatively high energy level, sufficient to penetrate silicon nitride layer 302. This results in a lower silicon oxide layer that is very pure and possesses excellent properties.

Further, a co-resulting annealing effect progressively improves the insulating density of silicon nitride layer 302. As the relative density of silicon nitride layer 302 increases the bonding force between silicon and nitrogen atoms also increase to progressively block oxygen radicals of increasingly high energy levels. As a result, the growth of lower silicon oxide layer 304 below silicon nitride layer 302 may be gradually stopped. That is, since the penetration of the oxygen radicals is blocked by annealed silicon nitride layer 302-1, the resulting absence of oxygen radicals bonding with the silicon atoms of substrate 300 stops the growth of lower silicon oxide layer 304.

Now, a process of forming upper silicon oxide layer 306 on silicon nitride layer 302 will be explained in some additional detail.

As noted, silicon substrate 300 having silicon nitride layer 302 formed thereon is loaded into the thermal oxidation processing system. Then, the oxygen radicals generated from the thermal oxidation processing system are passed through silicon nitride layer 302 to form lower silicon oxide layer 304 between silicon nitride layer 302 and silicon substrate 300. As lower silicon oxide layer 304 is being formed, silicon oxide layer 306 is also being grown on an upper surface of silicon nitride layer 302 by interaction of oxygen radicals with silicon atoms in the silicon nitride layer 302. That is, some of the oxygen radicals, unable to penetrate silicon nitride layer 302, nonetheless, form silicon oxide layer 306 on top of silicon nitride layer 302.

It should be noted that the growth rate for upper silicon oxide layer 306 is lower than that of lower silicon oxide layer 304. This is due to the fact that the number of oxygen radicals initially having sufficient energy to penetrate silicon nitride layer 320 is relatively great. Thus, relatively more of lower silicon oxide layer 304 is grown during an initial stage of the thermal oxidation process, while relatively more of upper silicon oxide layer 306 is grown during a later stage of the thermal oxidation process.

As silicon nitride layer 302 is formed, and as upper and lower silicon oxide layers 304 and 306 are grown above and below silicon nitride layer 302, the silicon atoms in silicon substrate 300 are consumed. Thus, as illustrated in FIGS. 5A through 5C, a first thickness D of silicon substrate 300 is gradually reduced to second thickness E, and then a third thickness G by the processes forming silicon nitride layer 302 and upper and lower silicon oxide layers 304 and 306.

Additionally, the thickness F of reduced density silicon nitride layer 302 is also reduced to a second thickness H to form annealed silicon nitride layer 302-1.

As described in reference to FIGS. 5A through 5C, a silicon nitride layer is formed using the plasma generated by applying microwave to the top of the silicon substrate in the present invention. Then, the silicon oxide layers are formed above and below the silicon nitride layer, using the oxygen radicals generated by the thermal oxidation process.

Normally, oxygen radicals have excellent reaction properties. Thus, the silicon oxide layer, which is formed by the oxygen radical having excellent reaction properties with silicon, has an excellent quality as an insulating layer since an interface trap generation rate is low and defects (e.g., weak Si—Si bonding, strained Si—O bonding, and Si dangling bonding) are not formed at the interface with the silicon substrate. Further, during the radical oxidation process using oxygen radicals, the any defect existing at the interface between the silicon substrate and the silicon nitride layer may be remedied by the effects of the reaction between the oxygen radicals and silicon atoms. That is, due to the affinity of oxygen radicals, broken and weak bonds with silicon atoms caused by breaking of the bonds between silicon and nitrogen atoms, that normally produce the various defects described, are remedied. In addition, nitride trapped charge (Qnt), otherwise deteriorating the insulation characteristics of the silicon nitride layer 302, may be completely removed by the thermal oxidation process used to form the silicon oxide layer(s).

FIG. 6 illustrates the sectional structure of a MOS transistor employing an insulating layer according to an embodiment of the present invention.

Referring to FIG. 6, a shallow trench isolation 402 is formed in a semiconductor substrate 400 composed of, for example, silicon, so as to define an active area and a field area. Then, a gate area 410, which is composed of a gate insulating layer 404, a gate electrode 406, and a spacer 408, is formed in the active area of semiconductor substrate 400.

A process of forming gate insulating layer 404 is an essential process to the implementation of this embodiment. Gate insulting layer 404 may be formed to have the same ONO structure as that described in the context of FIGS. 5A through 5C. That is, semiconductor substrate 400 may be loaded into a process chamber of a plasma processing system. The process chamber is maintained at an inner pressure of about 0.5 Torr and a temperature of about 500° C. Then, about 200 cc of argon gas is introduced and microwave energy is applied to generate an argon plasma. Then, about 150 cc of nitrogen gas is introduced, and a nitrification process is performed for about 120 to 140 seconds. As a result, a silicon nitride layer is formed with a thickness of about 15 to 20 Å (e.g., 19 Å) on semiconductor substrate 400.

Then, a thermal oxidation process is performed on semiconductor substrate 400 having the silicon nitride layer formed thereon. At this time, the process chamber is maintained at a temperature of about 950° C. and an inner pressure of about 6.5 Torr. Then, about 9 liters of oxygen gas and 1 liter of hydrogen gas are introduced into the process chamber to form a silicon nitride layer, and a thermal oxidation process is performed for about 80 to 90 seconds. As a result, upper and lower silicon oxide layers are formed by oxygen radicals, and gate insulating layer 404 having an ONO structure is formed with a total thickness of 60 to 70 Å (e.g., 67 Å).

Then, group III (for example, Boron) or group V (for example, Phosphorous or Arsenic) impurity ions are implanted into semiconductor substrate 400 having around gate electrode 406 to form source and drain regions (not shown). Then, a bit line 412 composed of a conductive material is formed in contact with the drain region, and a capacitor 420 composed of a lower electrode 414, a high-k dielectric layer 416, and an upper electrode 418 is formed in contact with the source region. A conventional metal process is performed to form metal lines 422 on upper electrode 418 of capacitor 420, and on the active area of a peripheral area respectively, so as to complete the fabrication of a MOS transistor.

As described above, in the formation of an insulating layer of an ONO structure according to embodiments of the invention, silicon oxide layers are formed below and on the silicon nitride layer using oxygen radicals having a good reaction property with silicon. Thus, as well as the quality of the silicon oxide layer, the quality of the silicon nitride layer can be improved by removing or minimizing the defects generated during the formation of the silicon nitride layer. As a result, the insulation property (dielectric constant) of the total insulating layer having an ONO structure is much improved, and the operating characteristics of a volatile or nonvolatile memory devices incorporating same may be improved.

Further, according to embodiments of the invention, a method of forming an insulating layer includes a thermal oxidation process once performed on a silicon substrate having a silicon nitride layer formed thereon, to form both upper and lower silicon oxide layers bracketing the silicon nitride layer. Thus, as compared to the conventional ONO-structure formation methods, in which an oxide layer, a nitride layer, and an oxide layer are sequentially stacked, fabrication time may be reduced and productivity improved.

The invention has been described in the context of several exemplary embodiments. However, it is to be understood that the scope of the invention is not limited to only the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

For example, the insulating layer form by embodiments of the invention has been illustrated in its formation within the context of silicon substrate. However, it need not be the case that the silicon material from which silicon atoms are drawn to form the inventive insulating layer be a substrate. Rather, any silicon material, (a substrate or a material silicon layer formed on a substrate) may serve this purpose and an insulating layer may be formed thereon.

What is claimed is:

1. A method of forming an insulating layer in a process chamber, the method comprising:
forming a first insulating layer on a silicon material; and thereafter
forming a second insulating layer between the silicon material and the first insulating layer.

2. The method of claim 1, wherein the first insulating layer is a silicon nitride layer, and forming the silicon nitride layer comprises:
forming an argon plasma in the process chamber, and thereafter,
introducing nitrogen gas into the process chamber.

3. The method of claim 2, wherein forming the argon plasma comprises applying microwave energy within the process chamber.

4. The method of claim 3, wherein the second insulating layer is a lower silicon oxide layer, and forming the lower silicon oxide layer comprises:
performing a thermal oxidation process on the silicon material after forming the first insulating layer thereon.

5. The method of claim 4, wherein the thermal oxidation process comprises, introducing oxygen gas and hydrogen gas into the process chamber.

6. The method of claim 5, wherein the lower silicon oxide layer is formed by oxygen radicals generated by the thermal oxidation process penetrating the first insulating layer and interacting with silicon atoms in the silicon material, and
wherein the density of the silicon nitride layer increases during the thermal oxidation process.

7. A method of forming an insulating layer on a silicon substrate in a process chamber, the method comprising:
forming a nitride layer on the silicon substrate; and thereafter,
performing a thermal oxidation process on the silicon substrate and nitride layer, wherein the thermal oxidation process generates energized oxygen radicals penetrating the nitride layer to form a lower oxide layer between the nitride layer and the silicon substrate.

8. The method of claim 7, wherein forming the nitride layer comprises performing a plasma nitrification process.

9. The method of claim 8, wherein the plasma nitrification process comprises:
introducing argon into the process chamber;
generating plasma from the argon; and thereafter,
introducing nitrogen gas into the process chamber.

10. The method of claim 9, wherein generating plasma from the argon comprises:
applying between about 1000 to 2000 Watts of microwave energy within the process chamber, while maintaining the process chamber at a pressure between about 0.3 to 0.7 Torr, and at a temperature of between about 400 to 600° C.

11. The method of claim 10, wherein the microwave energy is applied at about 1600 Watts at a pressure of about 0.5 Torr and a temperature of about 500° C.

12. The method of claim 7, wherein the thermal oxidation process comprises:
introducing oxygen gas and hydrogen gas into the process chamber.

13. The method of 12, wherein the thermal oxidation process within the process chamber is performed at a pressure of between about 6 to 7 Torr and at a temperature of between about 800 to 1050° C.

14. The method of claim 13, wherein the pressure is about 6.5 Torr and the temperature is about 950° C.

15. The method of claim 7, wherein the density of the nitride layer is increased during the thermal oxidization process.

16. A method of forming an insulating layer on a silicon substrate in a process chamber, the method comprising:
forming a nitride layer on the silicon substrate; and thereafter,
performing a thermal oxidation process on the silicon substrate and nitride layer, wherein the thermal oxidation process generates energized oxygen radicals penetrating the nitride layer, such that a lower silicon oxide layer is formed between the nitride layer and the silicon substrate, and such that an upper silicon oxide layer is simultaneously formed on an upper surface of the nitride layer.

17. The method of claim 16, wherein forming the nitride layer comprises performing a plasma nitrification process.

18. The method of claim 17, wherein the plasma nitrification process comprises:
introducing argon into the process chamber;
generating plasma from the argon; and thereafter,
introducing nitrogen gas into the process chamber.

19. The method of claim 17, wherein the density of the nitride layer is increased during the thermal oxidization process.
